(19) United States
(12) Patent Application Publication
(10) Pub. No.: US 2017/0117876 A1
(43) Pub. Date: Apr. 27, 2017

(54) METHOD AND ELECTRONIC DEVICE FOR DISPERSING NOISE SIGNAL

(71) Applicant: Samsung Electronics Co., Ltd, Gyeonggi-do (KR)

(72) Inventor: Jae Sub Youn, Gyeonggi-do (KR)

(21) Appl. No.: 15/301,942

(22) PCT Filed: Apr. 2, 2015
(86) PCT No.: PCT/KR2015/003329

§ 371 Date: Oct. 4, 2016

(30) Foreign Application Priority Data
Apr. 4, 2014 (KR) 10-2014-0040524

(51) Int. Cl. H03H 11/04; H05K 1/02; H03H 7/06

(52) U.S. Cl. CPC H03H 11/04; H03H 7/06; H05K 1/0216; H05K 2201/1006

(57) ABSTRACT

An electronic device comprises: a first signal line configured to transmit a noise signal; a filter configured to transmit at least part of the noise signal from the first signal line; and a second signal line configured to transmit the at least part of the noise signal transmitted via the filter, wherein both ends of the filter are connected to the first signal line and the second signal line.

### TECHNICAL FIELD

The present disclosure relates to a method and electronic device for dispersing a noise signal to protect an internal configuration of the electronic device.

### BACKGROUND ART

Electronic devices include circuit board having a plurality of electronic components, processor(s), and external sockets. The electronic devices may perform determined operations by transmitting/receiving electrical signals between the plurality of electronic components.

However, electrostatic discharge (ESD) due to charges accumulated outside or inside an electronic device or electrical overstress (EOS) due to abnormal voltage increase may affect electronic components included in the electronic device. Furthermore, when the influence due to the ESD or EOS is severe, at least part of the electronic components are damaged, so that the electronic device may not perform a determined operation.

### DISCLOSURE OF INVENTION

Various embodiments of the disclosure are directed to providing a method and electronic device for dispersing a noise signal to prevent a circuit of the electronic device from being damaged due to electrostatic discharge (ESD) and electrical overstress (EOS).

According to an embodiment of the present disclosure, an electronic device includes:

a first signal line configured to transmit a noise signal; a filter configured to transmit at least part of the noise signal from the first signal line; and a second signal line configured to transmit the at least part of the noise signal transmitted via the filter, wherein both ends of the filter are connected to the first signal line and the second signal line.

According to another embodiment of the present disclosure, a method of dispersing a noise signal includes: transferring the noise signal through a first signal line; transferring at least part of the noise signal through a filter; and transferring the at least part of the noise signal through a second signal, wherein both ends of the filter are connected to the first signal line and the second signal line.

### BRIEF DESCRIPTION OF DRAWINGS

FIG. 1 is a block diagram illustrating a network environment including an electronic device according to various embodiments of the present disclosure.

FIG. 2 is a block diagram illustrating a control module of an electronic device according to various embodiments of the present disclosure.

FIG. 3 is a view illustrating an internal circuit of an electronic device having a filter applied according to various embodiments of the present disclosure.

FIG. 4 is a view illustrating an internal circuit of an electronic device having a filter applied according to another embodiment of the present disclosure.

FIG. 5a is a view illustrating an internal circuit of an electronic device having a filter applied according to another embodiment of the present disclosure.

FIG. 5b is a view illustrating an internal circuit of an electronic device having a filter applied according to another embodiment of the present disclosure.

FIG. 5c is a view illustrating an internal circuit of an electronic device having a filter applied according to another embodiment of the present disclosure.

FIG. 6 is a view illustrating two electronic devices having different filters applied according to various embodiments of the present disclosure.

FIG. 7 is a flowchart illustrating a method of dispersing a noise signal in an electronic device according to various embodiments of the present disclosure.

FIG. 8 is a block diagram illustrating an electronic device according to various embodiments of the present disclosure.

### MODE FOR THE INVENTION

Hereinafter, embodiments of the present disclosure will be described in more detail with reference to the accompanying drawings to assist a person of ordinary skill in the art with a comprehensive understanding of various embodiments of the present disclosure as defined by the claims and their equivalents. Various embodiments of the present disclosure are shown in the drawings and related details are described but various modifications are possible and more embodiments may be introduced. Thus, it is intended that the present disclosure covers the modifications and variations of this disclosure provided they come within the scope of the appended claims and their equivalents. With respect to the descriptions of the drawings, like reference numerals refer to like elements.

As used herein, the terms “include,” “including,” “includes,” “characterize,” or “characterized in that” may indicate disclosed functions, operations, or existence of elements but these terms are not intended to exclude other functions, operations or elements. It should be further understood that the terms listed above, as used herein, may specify the presence of stated features, numbers, operations, elements, components, or combinations thereof but do not preclude the presence or addition of one or more other features, numbers, operations, elements, components, or combinations thereof.

In this specification, the expression “or” includes any or all combinations of words listed. For example, “A or B” may include A or include B or include both A and B.

The terms ‘first’ and/or ‘second’ may be used to describe various elements; however, the elements should not be limited by these terms. For example, the above expressions do not limit the order and/or importance of corresponding components. The expressions are used to distinguish one component from another component. For example, a first user device and a second user device are all user devices and represent different user devices. For example, a first component may be referred to as a second component and vice versa without departing from the scope of the present disclosure.

In this disclosure below, when one part (or element, device, etc.) is referred to as being ‘connected’ to another part (or element, device, etc.), it should be understood that the former can be ‘directly connected’ to the latter, or ‘electrically connected’ to the latter via an intervening part (or element, device, etc.). It will be further understood that when one component is referred to as being ‘directly connected’ or ‘directly linked’ to another component, it means that no intervening component is present.

Terms used in this specification are used to describe specific embodiments, and are not intended to limit the scope of the present disclosure. The terms of a singular form may include plural forms unless they have a clearly different meaning in the context.

Otherwise indicated herein, all the terms used herein, which include technical or scientific terms, may have the same meaning that is generally understood by a person skilled in the art. In general, the terms defined in the dictionary should be considered to have the same meaning as the contextual meaning of the related art, and, unless clearly defined herein, should not be understood abnormally or as having an excessively formal meaning.

Additionally, an electronic device according to an embodiment of the present disclosure may be a device having a noise signal dispersion function. For example, an electronic device may include at least one of smartphones, smart pads, tablet personal computers (PCs), mobile phones, video phones, e-book readers, desktop PCs, laptop PCs, netbook computers, personal digital assistants (PDAs), portable multimedia players (PMPs), MP3 players, mobile medical equipment, cameras, or wearable devices (for example, head-mounted-devices (HMDs) such as electronic glasses, electronic clothing, electronic bracelets, electronic necklaces, appcessories, electronic tattoos, or smartwatches).

According to an embodiment of the present disclosure, electronic devices may be smart home appliance having a noise signal dispersion function. Smart home appliance, for example, may include at least one of digital video disk (DVD) players, audio systems, refrigerators, air conditioners, vacuum cleaners, ovens, microwaves, washing machines, air purifiers, set-top boxes, TV boxes (for example, the Samsung HomeSync™, Apple TV™, or Google TV™), game consoles, electronic dictionaries, electronic key, camcorders, or electronic frames.

According to an embodiment of the present disclosure, an electronic device may include at least one of various medical devices having a noise signal dispersion function (for example, magnetic resonance angiography (MRA) devices, magnetic resonance imaging (MRI) devices, computed tomography (CT) devices, medical imaging devices, ultrasonic devices, etc.), navigation devices, global positioning system (GPS) receivers, event data recorders (EDRs), flight data recorders (FDRs), vehicle infotainment devices, marine electronic equipment (for example, marine navigation systems, gyro compasses, etc.), avionics, security equipment, car head units, industrial or household robots, financial institutions' automatic teller's machines (ATMs), and stores' point of sales (POS).

According to an embodiment of the present disclosure, an electronic device may include at least one of furniture or buildings/structures having a noise signal dispersion function, electronic boards, electronic signature receiving devices, projectors, or various measuring instruments (for example, water, electricity, gas, or radio signal measuring instruments). An electronic device according to an embodiment of the present disclosure may be one of the above-mentioned various devices or a combination thereof. Additionally, an electronic device according to an embodiment of the present disclosure may be a flexible device. Furthermore, it is apparent to those skilled in the art that an electronic device according to an embodiment of the present disclosure is not limited to the above-mentioned devices.

Hereinafter, an electronic device according to various embodiments of the present disclosure will be described in more detail with reference to the accompanying drawings. The term “user” in various embodiments may refer to a person using an electronic device or a device using an electronic device (for example, an artificial intelligent electronic device).

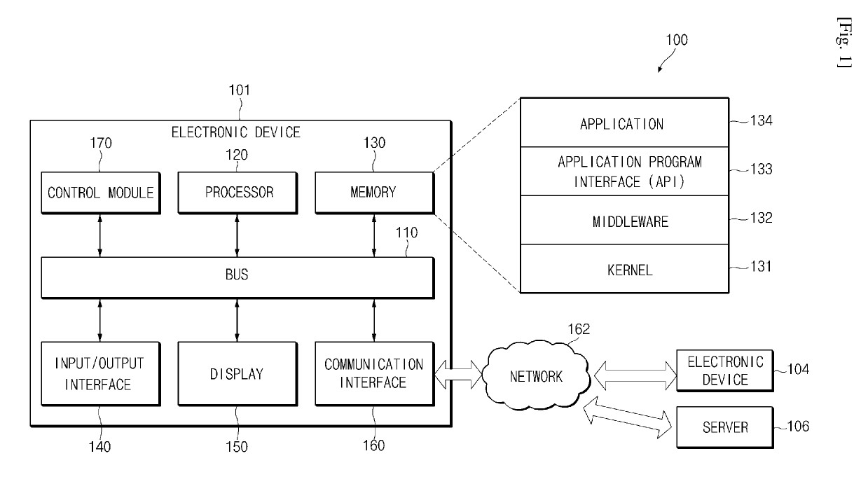

FIG. 1 is a block diagram illustrating a network environment 100 including an electronic device 101 according to various embodiments of the present disclosure. Referring to FIG. 1, the electronic device 101 may include a bus 110, a processor 120, a memory 130, an input/output interface 140, a display 150, a communication interface 160, and a control module 170.

The bus 110 may be a circuit connecting the above-mentioned components to each other and delivering a communication (for example, a control message) therebetween.

The processor 120, for example, receives an instruction from the above other components (for example, the memory 130, the input/output interface 140, the display 150, the communication interface 160, or the control module 170) through the bus 110, interprets the received instruction, and performs operations and data processing in response to the interpreted instruction.

The memory 130 may store an instruction or data received from the processor 120 or other components (for example, the input/output interface 140, the display 150, the communication interface 160, or the control module 170) or an instruction or data generated from the processor 120 or other components. The memory 130, for example, may include programming modules, for example, a kernel 131, a middleware 132, an application programming interface (API) 133, and an application 134. Each of the above-mentioned programming modules may be configured with software, firmware, hardware, or a combination thereof.

The kernel 131 may control or manage system resources (for example, the bus 110, the processor 120, or the memory 130) used for performing operation or functions implemented by the remaining other programming modules, for example, the middleware 132, the API 133, or the application 134. Additionally, the kernel 131 may provide an interface for accessing an individual component of the electronic device 101 from the middleware 132, the API 133, or the application 134 and controlling or managing the individual component.

The middleware 132 may serve as an intermediary role for exchanging data between the API 133 or the application 134 and the kernel 131 through communication. Additionally, in relation to job requests received from the applications 132, the middleware 134 may perform a control (for example, scheduling or load balancing) for the job requests by using a method of assigning a priority for using a system resource (for example, the bus 101, the processor 110, or the memory 120) of the electronic device 101 to at least one application among the applications 134.

The API 133, as an interface through which the application 134 controls a function provided from the kernel 131 or the middleware 132, may include at least one interface or function (for example, an instruction) for file control, window control, image processing, or character control.

According to various embodiments, the application 134 may include an SMS/MMS application, an e-mail application, a calendar application, an alarm application, a health care application (for example, an application for measuring an exercise amount or blood sugar), or an environmental information application (for example, an application for providing pressure, moisture, or temperature information). Additionally or alternatively, the application 134 may be an application relating to information exchange between the electronic device 101 and an external electronic device (for example, the electronic device 104). The application relating to information exchange, for example, may include a notification relay application for delivering specific information to the external electronic device or a device management application for managing the external electronic device.

For example, the notification relay application may have a function for delivering to an external electronic device (for example, the electronic device 104) notification information occurring from another application (for example, an SMS/MMS application, an e-mail application, a health care application, or an environmental information application) of the electronic device 101. Additionally or alternatively, the notification relay application 1134 may receive notification information from an external electronic device (for example, the electronic device 104) and may then provide the received notification information to a user. The device management application, for example, may manage (for example, install, delete, or update) a function (for example, turning on/off an external electronic device itself (or some components) or adjusting the brightness (or resolution) of a display) for at least part of an external electronic device (for example, the electronic device 104) communicating with the electronic device 101, an application operating in the external electronic device, or a service (for example, a call service or a message service) provided from the external electronic device.

According to various embodiments of the present disclosure, the application 134 may include an application designated according to the attribute (for example, a type of an electronic device) of the external electronic device (for example, the electronic device 104). For example, when an external electronic device is an MP3 player, the application 134 may include an application relating to music playback. Similarly, when an external electronic device is a mobile medical device, the application 134 may include an application relating to heath care. According to an embodiment of the present disclosure, the application 134 may include at least one of an application designated to the electronic device 101 or an application received from an external electronic device (for example, the server 106 or the electronic device 104).

The input/output interface 140 may deliver an instruction or data inputted from a user through an input/output device (for example, a sensor, a keyboard, or a touch screen), to the processor 120, the memory 130, the communication interface 160, or the first data processing module 170 through the bus 110. For example, the input/output interface 140 may provide data on a user's touch inputted through a touch screen to the processor 120. Additionally, the input/output interface 140 may output an instruction or data received from the processor 120, the memory 130, the communication interface 160, or the control module 170 through the bus 1310, through the input/output device (for example, a speaker or a display). For example, the input/output interface 140 may output voice data processed through the processor 120 to a user through a speaker.

The display 150 may display various information (for example, multimedia data or text data) to a user.

The communication interface 160 may connect a communication between the electronic device 101 and an external device (for example, the electronic device 104 or the server 106). For example, the communication interface 160 may communicate with the external device in connection to the network 162 through wireless communication or wired communication. The wireless communication may include at least one of wireless fidelity (WiFi), Bluetooth (BT), near field communication (NFC), global positioning system (GPS), or cellular communication (for example, 3G, LTE, LTE-A, CDMA, WCDMA, UMTS, WiBro, or GSM). The wired communication may include at least one of universal serial bus (USB), high definition multimedia interface (HDMI), recommended standard 232 (RS-232), or plain old telephone service (POTS), for example.

According to an embodiment of the present disclosure, the network 162 may be telecommunications network. The telecommunications network may include at least one of computer network, internet, internet of things, or telephone network. According to an embodiment of the present disclosure, a protocol (for example, transport layer protocol, data link layer protocol, or physical layer protocol) for communication between the electronic device 101 and an external device may be supported by at least one of the application 134, the application programming interface 133, the middleware 132, the kernel 131, or the communication interface 160.

The control module 160 may process at least part of information obtained from other components (for example, the processor 120, the memory 130, the input/output interface 140, or the communication interface 1360) and may output it to a user through various methods. For example, the control module 170 may control at least part of functions of the electronic device 101 to short-circuit an open filter on the basis of a noise signal of the electronic device 101, by using the processor 120 or separately from it.

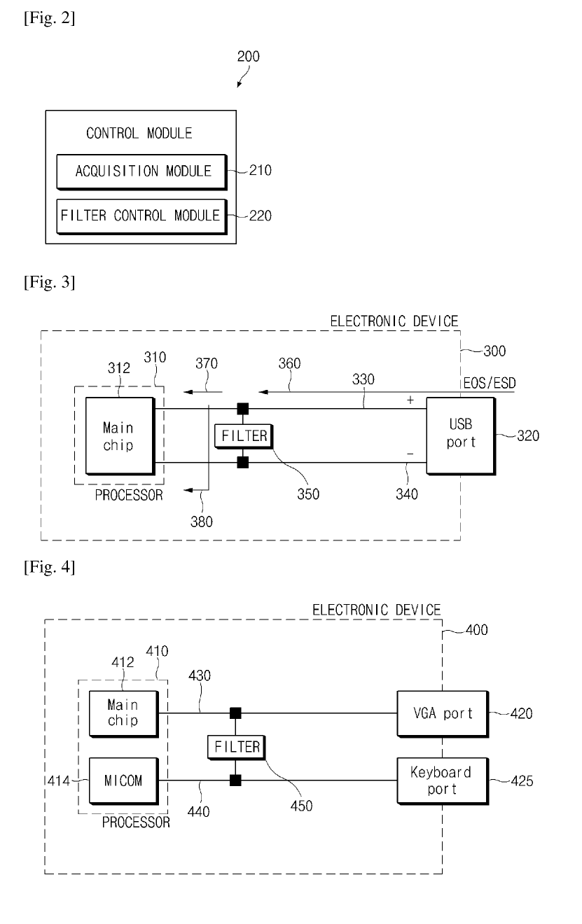

FIG. 2 is a block diagram 200 illustrating the control module 170 of an electronic device (for example, the electronic device 101) according to various embodiments of the present disclosure. Referring to FIG. 2, the control module 170 may include an acquisition module 210 and a filter control module 220.

The acquisition module 210 may obtain a detection result of a noise signal from at least one sensor (for example, at least one sensor included in the sensor module 840 of FIG. 8 to be described later) equipped inside or outside the electronic device 101.

The noise signal corresponds to an electro static discharge (ESD) signal or an electrical overstress (EOS) signal and may flow in from the outside of the electronic device 101 or may flow out from the inside to the outside of the electronic device.

The ESD signal or the EOS signal may be generated (or occurred) when charges accumulated inside or outside the electronic device 101 contact dielectrics or may be generated due to abnormal voltage increase. However, the causes that generate the ESD signal or the EOS signal are not limited thereto and the ESD signal or the EOS signal may be generated through other various causes.

For example, the ESD signal or the EOS signal may be generated when part of a user's body or an object contacts an input/output connector (for example, a USB port (or socket), an HDMI port, or a PS/2 port, etc.). That is, when charges accumulated around the input/output connector of the electronic device 101 contact dielectrics (for example, part of the user's body or the object), the ESD signal or the EOS signal may be generated.

The filter control module 220 may short-circuit the filter to allow at least part of a noise signal to flow into a filter inside the electronic device 101 on the basis of the obtained detection result of the noise signal by the acquisition module 210.

The filter maintains an open state normally and when the noise signal is generated, changes into a short-circuit state. According to various embodiments of the present disclosure, the filter may include at least one of a diode, a varistor, and a suppressor.

The operation that the open filter is short-circuited on the basis of the noise signal may be performed in response to a control signal (or a command) generated by the filter control module 220 but may be performed on the basis of characteristics between the noise signal and the filter without an additional control signal.

Hereinafter, referring to FIGS. 3 and 4, an operation for dispersing the noise signal is described through an embodiment having the filter applied.

FIG. 3 is a view illustrating an internal circuit of an electronic device 300 having a filter 350 applied according to various embodiments of the present disclosure. Referring to FIG. 3, the electronic device 300 may include a processor 310, an input/output connector 320 (for example, a USB port), a first signal line 330, a second signal line 340, and the filter 350. According to various embodiments of the present disclosure, the first signal line 330 or the second signal line 340 may include a trace of a PCB.

The processor 310 may include a main chip 312. The main chip 312 may be one chip or may be a chipset including a plurality of electronic chips. Additionally, the input/output connector 320 may correspond to a USB port. For example, an external input device (for example, a storage device or a mouse using USB) may be inserted into the input/output connector 320. According to various embodiments of the present disclosure, the external input device and the main chip 312 may communicate with each other by transmitting/receiving a signal through the first signal line 330 and the second signal line 340.

However, the first signal line 330 and the second signal line 340 may be a path through which a noise signal including ESD signals or EOS signals in addition to a communication signal transfers between the external input device and the main chip 312.

Since the noise signal damages the main chip 312, the electronic device 300 may include the filter 350 to protect the main chip 312 from the noise signal. In this case, the filter 350 may include at least one of a diode, a varistor, and suppressor and as shown in FIG. 3, both ends of the filter 350 may be connected to the first signal line 330 and the second signal line 340, respectively.

Reference numerals 360, 370, and 380 indicate a direction in which a noise signal flows. When the noise signal flows in through the input/output connector 320, the flowed noise signal may flow in a direction 360 and toward the main chip 312. However, when the filter 350 is equipped, part of the flowed noise signal flows in a direction 370 through the first signal line 330 and another part of the flowed noise signal flows in a direction 380 along the second signal line 340 through the filter 350.

That is, when the filter 350 is equipped, the flowed noise signal does not flow into the main chip 312 through one signal line but is dispersed through the filter 350, so that each of the dispersed noise signal respectively flow into the main chip 312 along the first signal line 330 and the second signal line 340. Accordingly, the filer 350 may prevent the damage of the main chip 312, which is caused when all noise signals flow into the main chip 312 through one single line (for example, the first signal line).

However, the above-mentioned flow of a noise signal is just an example, and according to various embodiments of the present disclosure, various flows of a noise signal may be applied.

For example, a noise signal may be flow from the outside through the second signal line 340. Furthermore, on the other hand, a noise signal may be generated inside of the electronic device 300 and may flow to the outside through the first signal line 330 or the second signal line 340.

The first signal line 330 and the second signal line 340 shown in FIG. 3 may be in a parallel relationship and may correspond to a differential signal. For example, the input/output connector 320 may include a USB port, an HDMI port, a PCI Express port, a Serial ATA port, and an Ethernet over twisted pair port.

FIG. 4 is a view illustrating an internal circuit of an electronic device 400 having a filter 450 applied according to another embodiment of the present disclosure. Referring to FIG. 4, the electronic device 400 may include a processor 410, a first input/output connector 420 (for example, a VGA port) a second input/output connector 425 (for example, a keyboard (PS/2) port), a first signal line 430, a second signal line 440, and the filter 450.

The processor 410 may include a main chip 412 and a MICOM 414. The main chip 412 may be connected to the first input/output connector 420 through the first signal line 430 and the MICOM 414 may be connected to the second input/output connector 425 through the second signal 440.

In this case, the first input/output connector 420 may correspond to a VGA port and the second input/output connector 425 may correspond to a keyboard port (for example, a PS/2 port). For example, a VGA cable of a VGA display device (not shown) may be mounted on or inserted into the first input/output connector 420. Additionally, a keyboard (not shown) may be mounted on or inserted into the second input/output connector 425.

In this case, the VGA display device and the main chip 412 may communicate with each other as transmitting/receiving a signal through the first signal line 430, and the keyboard and the main chip 414 may communicate with each other as transmitting/receiving a signal through the second signal line 440.

However, the first signal line 430 and the second signal line 440 may be a path through which a noise signal including ESD signals or EOS signals transfers.

Since the noise signal damages the main chip 412 and/or the MICOM 414, the electronic device 400 may include the filter 450 to protect the main chip 412 and/or the MICOM 414 from the noise signal.

As similar to FIG. 3, when a noise signal flows in from the outside through the first input/output connector 420 or the second input/output connector 425, the flowing signal may be dispersed through the filter 450. Through this, the main chip 412 and the MICOM 414 may be protected.

When a noise signal is generated from the inside of the electronic device 400 and flows into the outside, the noise signal may be dispersed through the filter 450.

The first signal line 430 and/or the second signal line 440 shown in FIG. 4 may correspond to a single-ended signal or a high speed signal. For example, the first input/output connector 420 and/or the second input/output connector 425 may include a Parallel ATA port, a TRS phone connectors port, a RCA jacks port, and a PCI port in addition to the keyboard port and the VGA port.

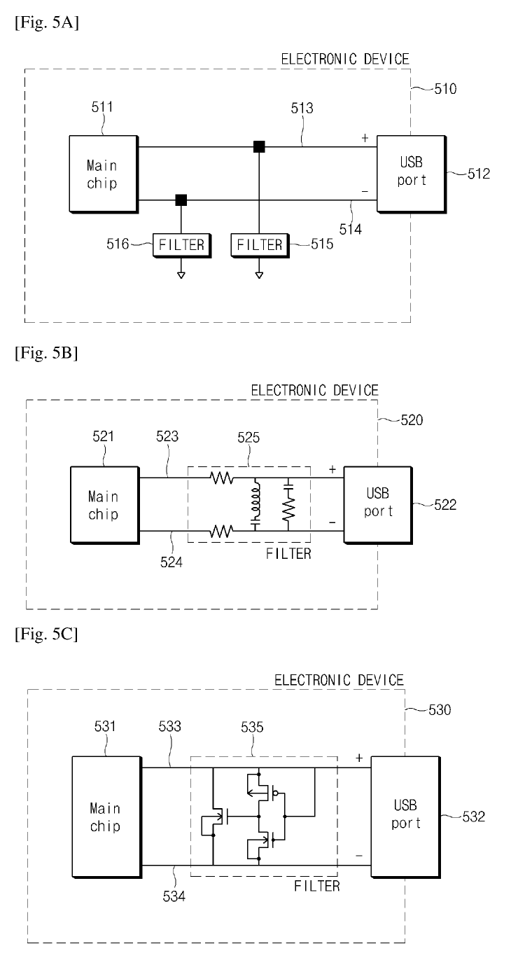

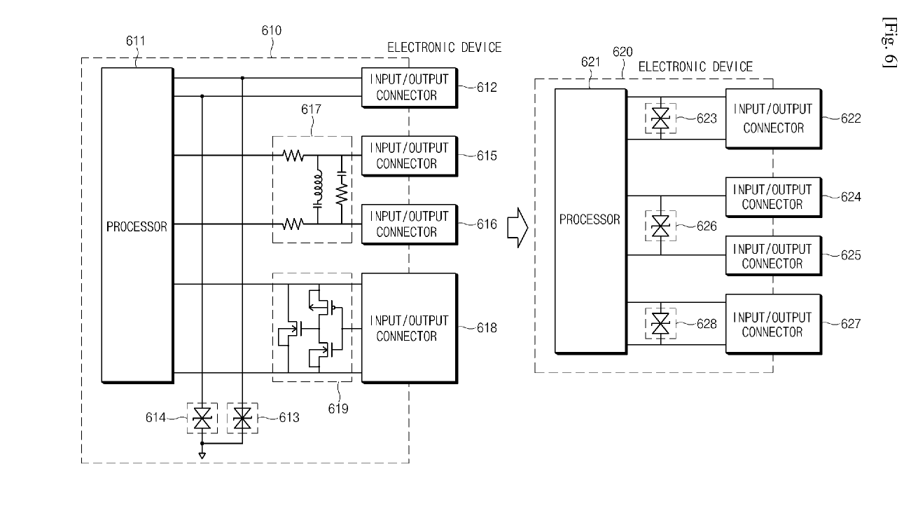

Hereinafter, various embodiments for dispersing a noise signal are described with reference to FIGS. 5a to 5c.

FIG. 5a is a view illustrating an internal circuit of an electronic device 510 having filters 515 and 516 applied according to another embodiment of the present disclosure. Referring to FIG. 5a, the electronic device 510 may include a main chip 511, a USB port 512, a first signal line 513, a second signal line 514, the first filter 515, and the second filter 516.

Unlike the case that the both ends of the filter 350 shown in FIG. 3 are respectively connected to the first signal line 330 and the second signal line 340, one ends of the first filter 515 and the second filter 516 of FIG. 5a are respectively connected to the first signal line 513 and the second signal 514, and the other ends are grounded.

In this case, each of the first filter 515 and the second filter 516 may ground at least part of a flowing-in noise signal or a flowing-out noise signal.

At this point, like the filter 350 of FIG. 3, each of the first filter 515 and the second filter 516 may include at least one of a diode, a varistor, and a suppressor.

FIG. 5b is a view illustrating an internal circuit of an electronic device 520 having a filter 525 applied according to another embodiment of the present disclosure. Referring to FIG. 5b, the electronic device 520 may include a main chip 521, a USB port 522, a first signal line 523, a second signal line 524, and the filter 525.

Unlike the case that the both ends of the filter 350 shown in FIG. 3 are respectively connected to the first signal line 330 and the second signal line 340, the filter 525 of FIG. 5b may connect the main chip 521 and the USB port 522 in series as a 2-port. Additionally, the filter 525 may include an RLC circuit.

In this case, the filter 525 may disperse at least part of a flowing-in noise signal or a flowing-out noise signal.

FIG. 5c is a view illustrating an internal circuit of an electronic device 530 having a filter 535 applied according to another embodiment of the present disclosure. Referring to FIG. 5c, the electronic device 530 may include a main chip 531, a USB port 532, a first signal line 533, a second signal line 534, and the filter 535.

Unlike the case that the both ends of the filter 350 shown in FIG. 3 are respectively connected to the first signal line 330 and the second signal line 340, the filter 535 of FIG. 5c may connect the main chip 531 and the USB port 532 in series as a 2-port. Additionally, the filter 535 may include a transistor.

In this case, the filter 535 may disperse at least part of a flowing-in noise signal or a flowing-out noise signal.

All the filters 515, 516, 525, and 535 of FIGS. 5a to 5c may disperse a noise signal but as compared to the filter 350 or 450 of FIG. 3 or 4, may require more devices and spaces.

Hereinafter, referring to FIG. 6, the electronic device 610 using the filters 515, 516, 525, and 535 of FIGS. 5a to 5c is compared to the electronic device 620 using the filter 350 or 450 of FIG. 3 or 4.

FIG. 6 is a view illustrating two electronic devices 610 and 620 having different filters applied according to various embodiments of the present disclosure.

Referring to the left of FIG. 6, the electronic device 610 may include a processor 611, a first input/output connector 612, a first filter 613, a second filter 614, a second input/output connector 615, a third input/output connector 616, a first filter 617, a fourth input/output connector 618, and a fourth filter 619.

In this case, the processor 611 may include a main chip and a MICOM communicating with at least one of the first input/output connector 612, the second input/output connector 615, the third input/output connector 616, and the fourth input/output connector 618.

Additionally, the first filter 613 and the second filter 614 correspond to the first filter 515 and the second filter 516 of FIG. 5a, respectively, and the third filter 617 corresponds to the filter 525 of FIG. 5b, and the fourth filter 619 corresponds to the filter 535 of FIG. 5c.

Referring to the right of FIG. 6, the electronic device 620 may include a processor 621, a first input/output connector 622, a first filter 623, a second input/output connector 624, a third input/output connector 625, a second filter 626, a fourth input/output connector 627, and a third filter 628.

As compared to the third filter 617 or the fourth filter 619, the first filter 623, the second filter 626, or the third filter 628 of the electronic device 620 may use devices less. Additionally, the first filter 623, the second filter 626, or the third filter 628 of the electronic device 620 correspond to the first filter 613 or the second filter 614 of the electronic device 610 but do not include a direct ground structure. Accordingly, the first filter 623, the second filter 626, and the third filter 628 of the electronic device 620 may not include an additional via area for grounding.

Like the first filter 623, the second filter 626, and the third filter 628 of the electronic device 620, a filter having both ends respectively connected to a first signal line and a second signal line, and not grounded directly may contribute to reducing the number of components in an electronic device, the size of a PCB, and manufacturing costs.

When the size of the PCB in the electronic device is reduced, a relatively broad utilization space may be obtained in the same housing. For example, a relatively broad space for mounting a battery may be obtained and product competitiveness may be enhanced.

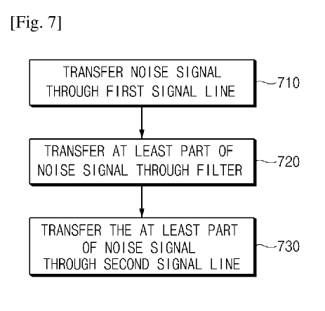

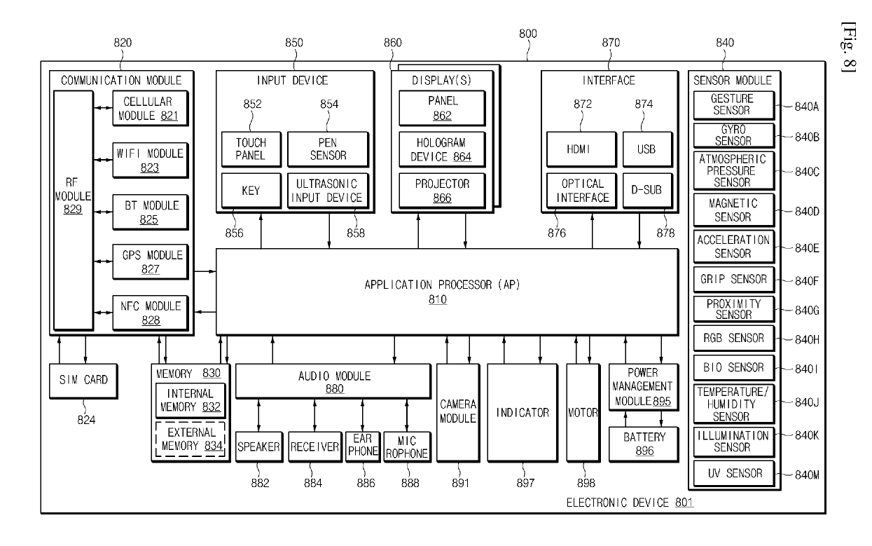

FIG. 7 is a flowchart illustrating a method of dispersing a noise signal in an electronic device 300 according to various embodiments of the present disclosure. The method of dispersing a noise signal according to an embodiment of FIG. 7 includes time-sequentially processed operations in an electronic device according to various embodiments of FIGS. 1 to 6. Accordingly, even if contents are omitted, contents described in relation to the electronic device of FIGS. 1 to 6 may be applied to the method of dispersing a noise signal according to the embodiment of FIG. 7.

In operation 710, a noise signal flowing into an electronic device from outside or flowing out from an electronic device may transfer through a first signal line.

In operation 720, the noise signal flowing into an electronic device or flowing out from an electronic device may be dispersed, and at least part of the dispersed noise signal may transfer through a filter.

In operation 730, the at least part of the dispersed noise signal transferring through the filter may transfer through a second signal line. Additionally, the remaining noise signal not transferring through the filter in operation 720 may continuously transfer along the first signal line.

The order of operations 710 to 730 of FIG. 7 is just an example and thus present disclosure is not limited thereto. That is, the order between the above-mentioned operations may vary and some of the operations may be performed simultaneously. Additionally, the above mentioned operations may be repeated periodically at each predetermined time and may be performed again on the basis of a user input inputted from a user.

FIG. 8 is a block diagram illustrating an electronic device 801 according to various embodiments of the present disclosure. The electronic device 801, for example, may configure all or part of the above-mentioned electronic device 101 shown in FIG. 1. Referring to FIG. 8, the electronic device 801 includes at least one application processor (AP) 810, a communication module 820, a subscriber identification module (SIM) card 824, a memory 830, a sensor module 840, an input device 850, a display 860, an interface 870, an audio module 880, a camera module 891, a power management module 895, a battery 896, an indicator 897, and a motor 898.

The AP 810 may control a plurality of hardware or software components connected to the AP 810 and also may perform various data processing and operations with multimedia data by executing an operating system or an application program. The AP 810 may be implemented with a system on chip (SoC), for example. According to an embodiment of the present disclosure, the AP 810 may further include a graphic processing unit (GPU) (not shown).

The communication module 820 (for example, the communication interface 160) may perform data transmission through a communication between other electronic devices (for example, the electronic device 104 or the server 106) connected to the electronic device 801 (for example, the electronic devices 101) via a network. According to an embodiment of the present disclosure, the communication module 820 may include a cellular module 821, a Wi-Fi module 823, a BT module 825, a GPS module 827, an NFC module 828, and a radio frequency (RF) module 829.

The cellular module 821 may provide voice calls, video calls, text services, or internet services through a communication network (for example, LTE, LTE-A, CDMA, WCDMA, UMTS, WiBro, or GSM). Additionally, the cellular module 821 may distinguish and authenticate an electronic device in a communication network by using a subscriber identification module (for example, the SIM card 824), for example. According to an embodiment of the present disclosure, the cellular module 821 may perform at least part of a function that the AP 810 provides. For example, the cellular module 821 may perform at least part of a multimedia control function.

According to an embodiment of the present disclosure, the cellular module 821 may further include a communication processor (CP). Additionally, the cellular module 821 may be implemented with SoC, for example. As shown in FIG. 8, components such as the cellular module 821 (for example, a CP), the memory 830, or the power management module 895 are separated from the AP 810, but according to an embodiment of the present disclosure, the AP 810 may be implemented including some of the above-mentioned components (for example, the cellular module 821).

According to an embodiment of the present disclosure, the AP 810 or the cellular module 821 (for example, a CP) may load instructions or data, which are received from a nonvolatile memory or at least one of other components connected thereto, into a volatile memory and then may process them. Furthermore, the AP 810 or the cellular module 821 may store data received from or generated by at least one of other components in a nonvolatile memory.

Each of the Wi-Fi module 823, the BT module 825, the GPS module 827, and the

NFC module 828 may include a processor for processing data transmitted/received through a corresponding module. Although the cellular module 821, the Wi-Fi module 823, the BT module 825, the GPS module 827, and the NFC module 828 are shown as separate blocks in FIG. 8, according to an embodiment of the present disclosure, some (for example, at least two) of the cellular module 821, the Wi-Fi module 823, the BT module 825, the GPS module 827, and the NFC module 828 may be included in one integrated chip (IC) or an IC package. For example, at least some (for example, a CP corresponding to the cellular module 821 and a Wi-Fi processor corresponding to the Wi-Fi module 823) of the cellular module 825, the Wi-Fi module 827, the BT module 828, the GPS module 821, and the NFC module 823 may be implemented with one SoC.

The RF module 829 may be responsible for data transmission, for example, the transmission of an RF signal. Although not shown in the drawings, the RF module 829 may include a transceiver, a power amp module (PAM), a frequency filter, or a low noise amplifier (LNA). Additionally, the RF module 829 may further include components for transmitting/receiving electromagnetic waves on a free space in a wireless communication, for example, conductors or conducting wires. Although the cellular module 821, the Wi-Fi module 823, the BT module 825, the GPS module 827, and the NFC module 828 share one RF module 829 shown in FIG. 8, according to an embodiment of the present disclosure, at least one of the cellular module 821, the WiFi module 823, the BT module 825, the GPS module 827, and the NFC module 828 may perform the transmission of an RF signal through an additional RF module.

The SIM card 824 may be a card including a subscriber identification module and may be inserted into a slot formed at a specific position of an electronic device. The SIM card 824 may include unique identification information (for example, an integrated circuit card identifier (ICCID)) or subscriber information (for example, an international mobile subscriber identity (IMSI)). According to various embodiments of the present disclosure, the SIM card 824 may be omitted or may be replaced with an OEM identification number.

The memory 830 (for example, the memory 130) may include an internal memory 832 or an external memory 834. The internal memory 832 may include at least one of a volatile memory (for example, dynamic RAM (DRAM), static RAM (SRAM), synchronous dynamic RAM (SDRAM)) and a non-volatile memory (for example, one time programmable ROM (OTPROM), programmable ROM (PROM), erasable and programmable ROM (EPROM), electrically erasable and programmable ROM (EEPROM), mask ROM, flash ROM, NAND flash memory, and NOR flash memory)

According to an embodiment of the present disclosure, the internal memory 832 may be a Solid State Drive (SSD). The external memory 834 may further include flash drive, for example, compact flash (CF), secure digital (SD), micro secure digital (Micro-SD), mini secure digital (Mini-SD), extreme digital (xD), or memorystick. The external memory 834 may be functionally connected to the electronic device 801 through various interfaces. According to an embodiment of the present disclosure, the electronic device 801 may further include a storage device (or a storage medium) such as a hard drive.

The sensor module 840 measures physical quantities or detects an operating state of the electronic device 801, thereby converting the measured or detected information into electrical signals. The sensor module 840 may include at least one of a gesture sensor 840A, a gyro sensor 840B, a pressure sensor 840C, a magnetic sensor 840D, an acceleration sensor 840E, a grip sensor 840F, a proximity sensor 840G, a color sensor 840H (for example, a red, green, blue (RGB) sensor), a bio sensor 8401, a temperature/humidity sensor 840J, an illumination sensor 840K, and an ultra violet (UV) sensor 840M. Additionally/alternately, the sensor module 840 may include an E-nose sensor (not shown), an electromyography (EMG) sensor, an electroencephalogram (EEG) sensor (not shown), an electrocardiogram (ECG) sensor (not shown), an infra red (IR) sensor (not shown), an iris sensor (not shown), or a fingerprint sensor (not shown). The sensor module 840 may further include a control circuit for controlling at least one sensor therein.

The user input device 850 may include a touch panel 852, a (digital) pen sensor 854, a key 856, or an ultrasonic input device 858. The touch panel 852 may recognize a touch input through at least one of capacitive, resistive, infrared, or ultrasonic methods, for example. Additionally, the touch panel 852 may further include a control circuit. In the case of the capacitive method, both direct touch and proximity recognition are possible. The touch panel 852 may further include a tactile layer. In this case, the touch panel 852 may provide a tactile response to a user.

The (digital) pen sensor 854 may be implemented through a method similar or identical to that of receiving a user's touch input or an additional sheet for recognition. The key 856 may include a physical button, a touch key, an optical key, or a keypad, for example. The ultrasonic input device 858, as a device checking data by detecting sound waves through a microphone (for example, the microphone 888) in the electronic device 801, may provide wireless recognition through an input tool generating ultrasonic signals. According to an embodiment of the present disclosure, the electronic device 801 may receive a user input from an external device (for example, a computer or a server) connected to the electronic device 200 through the communication module 820.

The display 860 (for example, the display 150) may include a panel 862, a hologram device 864, or a projector 866. The panel 862 may include a liquid-crystal display (LCD) or an active-matrix organic light-emitting diode (AM-OLED). The panel 862 may be implemented to be flexible, transparent, or wearable, for example. The panel 862 and the touch panel 852 may be configured with one module. The hologram device 864 may show three-dimensional images in the air by using the interference of light. The projector 866 may display an image by projecting light on a screen. The screen, for example, may be placed inside or outside the electronic device 801. According to an embodiment of the present disclosure, the display 860 may further include a control circuit for controlling the panel 862, the hologram device 864, or the projector 866.

The interface 870 may include a high-definition multimedia interface (HDMI) 872, a universal serial bus (USB) 874, an optical interface 876, or a D-subminiature (sub) 878, for example. The interface 870 may be included in the communication interface 160 shown in FIG. 1, for example. Additionally/alternately, the interface 870 may include a mobile high-definition link (MHL) interface, a secure Digital (SD) card/multi-media card (MMC) interface, or an infrared data association (IrDA) standard interface.

The audio module 880 may convert sound and electrical signals in both directions. At least some components of the audio module 880 may be included in the input/output interface 140 shown in FIG. 1, for example. The audio module 880 may process sound information inputted/outputted through a speaker 882, a receiver 884, an earphone 886, or a microphone 888.

The camera module 891, as a device for capturing a still image and a video, may include at least one image sensor (for example, a front sensor or a rear sensor), a lens (not shown), an image signal processor (ISP) (not shown), or a flash (not shown) (for example, an LED or a xenon lamp).

The power management module 895 may manage the power of the electronic device 801. Although not shown in the drawings, the power management module 895 may include a power management integrated circuit (PMIC), a charger integrated circuit (IC), or a battery or fuel gauge, for example.

The PMIC may be built in an IC or SoC semiconductor, for example. A charging method may be dispersed as a wired method and a wireless method. The charger IC may charge a battery and may prevent overvoltage or overcurrent flow from a charger. According to an embodiment of the present disclosure, the charger IC may include a charger IC for at least one of a wired charging method and a wireless charging method. As the wireless charging method, for example, there is a magnetic resonance method, a magnetic induction method, or an electromagnetic method. An additional circuit for wireless charging, for example, a circuit such as a coil loop, a resonant circuit, or a rectifier circuit, may be added.

The battery gauge may measure the remaining amount of the battery 896, or a voltage, current, or temperature of the battery 396 during charging. The battery 896 may store or generate electricity and may supply power to the electronic device 801 by using the stored or generated electricity. The battery 896, for example, may include a rechargeable battery or a solar battery.

The indicator 897 may display a specific state of the electronic device 801 or part thereof (for example, the AP 810), for example, a booting state, a message state, or a charging state. The motor 898 may convert electrical signals into mechanical vibration. Although not shown in the drawings, the electronic device 801 may include a processing device (for example, a GPU) for mobile TV support. A processing device for mobile TV support may process media data according to the standards such as digital multimedia broadcasting (DMB), digital video broadcasting (DVB), or media flow.

Each of the above-mentioned components of the electronic device according to various embodiments of the present disclosure may be configured with at least one component and the name of a corresponding component may vary according to the kind of an electronic device. Hardware according to an embodiment of the present disclosure may be configured including at least one of the above-mentioned components or additional other components. Additionally, some of components in hardware according to an embodiment of the present disclosure are configured as one entity, so that functions of previous corresponding components are performed identically.

The term “module” used in this disclosure, for example, may mean a unit including a combination of at least one of hardware, software, and firmware. The term “module” and the term “unit”, “logic”, “logical block”, “component”, or “circuit” may be interchangeably used. “module” may be a minimum unit or part of an integrally configured component. “module” may be a minimum unit performing at least one function or part thereof. “module” may be implemented mechanically or electronically. For example, “module” according to various embodiments of the present disclosure may include at least one of an application-specific integrated circuit (ASIC) chip performing certain operations, field-programmable gate arrays (FPGAs), or a programmable-logic device, all of which are known or to be developed in the future.

According to various embodiments, at least part of a device (for example, modules or functions thereof) or a method (for example, operations) according to this disclosure, for example, as in a form of a programming module, may be implemented using an instruction stored in computer-readable storage media. When at least one processor (for example, the processor 120) executes an instruction, it may perform a function corresponding to the instruction. The computer-readable storage media may include the memory 130, for example. At least part of a programming module may be implemented (for example, executed) by processor 120, for example. At least part of a programming module may include a module, a program, a routine, sets of instructions, or a process to perform at least one function, for example.

The computer-readable storage media may include Magnetic Media such as a hard disk, a floppy disk, and a magnetic tape, Optical Media such as Compact Disc Read Only Memory (CD-ROM) and Digital Versatile Disc (DVD), Magneto-Optical Media such as Floptical Disk, and a hardware device especially configured to store and perform a program instruction (for example, a programming module) such as Read Only Memory (ROM), Random Access Memory (RAM), and flash memory. Additionally, a program instruction may include high-level language code executable by a computer using an interpreter in addition to machine code created by a complier. The hardware device may be configured to operate as at least one software module to perform an operation of this disclosure and vice versa.

A module of a programming module according to various embodiments may include at least one of the above-mentioned components or additional other components. Or, some programming modules may be omitted. Operations performed by a module, a programming module, or other components according to various embodiments of the present disclosure may be executed through a sequential, parallel, repetitive or heuristic method. Additionally, some operations may be executed in a different order or may be omitted. Or, other operations may be added.

According to various embodiments of the present disclosure, a circuit of an electronic device is protected by dispersing a noise signal.

Also, embodiments shown in this specification and drawings are provided as specific examples to describe technical content easily and help understanding and also do not limit the scope of the present disclosure. Accordingly, it should be interpreted that besides the embodiments listed herein, all modifications or modified forms derived based on the technical ideas of the present disclosure are included in the scope of the present disclosure.

1] An electronic device comprising:
a first signal line configured to transmit a noise signal;
a filter configured to transmit at least part of the noise signal from the first signal line; and
a second signal line configured to transmit the at least part of the noise signal transmitted via the filter,
wherein both ends of the filter are connected to the first signal line and the second signal line.

2] The electronic device according to claim 1, wherein the filter comprises at least one of a diode, a varistor, and a suppressor.

3] The electronic device according to claim 1, wherein the noise signal corresponds to an electro static discharge (ESD) signal or an electrical overstress (EOS) signal.

4] The electronic device according to claim 1, wherein the noise signal flows from an outside into an inside of the electronic device through an input/output connector.

5] The electronic device according to claim 1, wherein the first signal line and the second signal are in a parallel.

6] The electronic device according to claim 5, wherein the first signal line and the second signal line connect an input connector and a processor.

7] The electronic device according to claim 5, wherein the first signal line connects an input/output connector and a processor, and the second signal line connects another input/output connector and the processor.

8] The electronic device according to claim 1, wherein the filter is short-circuited when transmitting the noise signal in an open state.

9] The electronic device according to claim 1, wherein the first signal line and/or the second signal line comprises a trace of a PCB(printed circuit board).

10] The electronic device according to claim 1, wherein the filter is not grounded directly.

11] The electronic device according to claim 1, wherein the at least part of the noise signal transmitted through the second signal leaks into an outside through an input/output connector.

12] The electronic device according to claim 1, wherein the first signal line or the second signal line corresponds to one of a differential signal, a single ended signal, and a high speed signal.

13] A method of dispersing a noise signal, the method comprising:
transferring the noise signal through a first signal line;
transferring at least part of the noise signal through a filter; and
transferring the at least part of the noise signal through a second signal,
wherein both ends of the filter are connected to the first signal line and the second signal line.

14] The method according to claim 13, wherein the noise signal flows into the first signal line from an outside through an input/output connector.

15] The method according to claim 13, wherein the transferring of the at least part of the noise signal through the filter comprises:
detecting the noise signal; and
short-circuiting the filter based on the detection result.
